(19) United States
(12) Patent Application Publication
(10) Pub. No.: US 2006/0086979 A1
(43) Pub. Date: Apr. 27, 2006

(54) Metal wiring, method of manufacturing the same, TFT substrate having the same, method of manufacturing TFT substrate and display device having the same

(76) Inventors: Yang-Sun Kim, Suwon-si (KR); Taek-Hee Kim, Seoul (KR)

Correspondence Address: CANTOR COLBURN, LLP, 55 GRIFFIN ROAD SOUTH, BLOOMFIELD, CT, 06002, US

(21) Appl. No.: 11/249,850

(22) Filed: Oct. 13, 2005

(30) Foreign Application Priority Data
Oct. 21, 2004 (KR) 2004-84526

(51) Int. Cl. H01L 27/12

(52) U.S. Cl. 257/347

(57) ABSTRACT

A TFT substrate includes a transparent substrate, a scan line, a data line, a switching device and a pixel electrode. The scan line is formed on the transparent substrate. The data line is formed on the transparent substrate such that the data line is electrically insulated from the scan line. The switching device includes a gate electrode that is electrically connected to the scan line, a source electrode that is electrically connected to the data line, and a drain electrode. The pixel electrode is electrically connected to the drain electrode. At least one of the scan line and the data line includes a first metal layer, a metal oxide layer formed on the first metal layer, and a second metal layer formed on the metal oxide layer. Therefore, the metal oxide layer prevents corrosion of the first metal layer during manufacturing the TFT substrate.

This application claims priority to Korean Patent Application No. 2004-84526 filed on Oct. 21, 2004 and all the benefits accruing therefrom under 35 U.S.C. § 119, and the contents of which in its entirety are herein incorporated by reference in.

### BACKGROUND OF THE INVENTION

1. Field of the Invention

The present invention relates to a metal wiring, a method of manufacturing the metal wiring, a TFT substrate, a method of manufacturing the TFT substrate, and a display device having the metal wiring. More particularly, the present invention relates to a metal wiring having a multi-layered structure, a method of manufacturing the metal wiring, a TFT substrate, a method of manufacturing the TFT substrate, and a display device having the metal wiring.

2. Description of the Related Art

A liquid crystal display (LCD) device displays an image by using liquid crystals. The LCD device includes a thin film transistor (TFT) substrate, a color filter substrate facing the TFT substrate, and a liquid crystal layer disposed between the TFT substrate and the color filter substrate. The TFT substrate includes a plurality of scan lines, a plurality of data lines, and a plurality of TFTs arranged in a matrix shape. The TFT includes a gate electrode that is electrically connected to one of the scan lines, a source electrode that is electrically connected to one of the data lines, and a drain electrode that is electrically connected to a pixel electrode. When the TFT is turned on, a pixel voltage is applied to the pixel electrode of the TFT substrate to generate an electrical field between the TFT substrate and the color filter substrate. As a result, an arrangement of the liquid crystal molecules of the liquid crystal layer is altered to change the optical transmissivity of the liquid crystal layer, so that an image is displayed. The LCD device has many advantages such as a thin thickness, a lightweight design, and low power consumption, etc. Therefore, the LCD device is employed by various electronic devices including, but not limited to, mobile phones, computer monitors, etc.

As the LCD device becomes bigger and more precise, an RC time constant of the scan line increases and a signal is delayed which deteriorates display quality. When an electrical resistivity of the scan line becomes higher, signals along the scan line or the data line become irregular and the display brightness becomes non-uniform. Furthermore, as the number of scan line increases, the time allowed for charging the pixel electrode becomes shorter. Therefore, the scan lines having low resistivity are required. In order to reduce electrical resistivity, scan lines having a double-layered structure have been developed. In detail, the scan lines have an aluminum (Al) layer and a metal layer having a high melting point.

However, during a photolithography process for forming the scan lines, an aluminum layer may be corroded and induce deterioration of the scan lines.

### BRIEF SUMMARY OF THE INVENTION

The present invention provides a metal wiring capable of reducing deterioration.

The present invention also provides a method of manufacturing the above-mentioned metal wiring.

The present invention also provides a TFT substrate having the above-mentioned metal wiring.

The present invention also provides a method of manufacturing the above-mentioned TFT substrate.

The present invention also provides a display device having the above-mentioned display panel.

In an exemplary metal wiring according to the present invention, the metal wiring includes a first metal layer, a metal oxide layer and a second metal layer. The first metal layer is formed on a substrate. The metal oxide layer is formed on the first metal layer to prevent corrosion of the first metal layer. The second metal layer is formed on the metal oxide layer.

In an exemplary method of manufacturing a metal wiring according to the present invention, a first metal layer is formed on a substrate. The first metal layer is exposed to oxygen gas (O₂) to form a metal oxide layer on the first metal layer. A second metal layer is formed on the metal oxide layer, and then the first metal layer, the metal oxide layer and the second metal layer are patterned to form the metal wiring.

In an exemplary TFT substrate according to the present invention, the TFT substrate includes a transparent substrate, a scan line, a data line, a switching device and a pixel electrode. The scan line is formed on the transparent substrate. The data line is formed on the transparent substrate such that the data line is electrically insulated from the scan line. The switching device includes a gate electrode that is electrically connected to the scan line, a source electrode that is electrically connected to the data line, and a drain electrode. The pixel electrode is electrically connected to the drain electrode. At least one of the scan line and the data line includes a first metal layer, a metal oxide layer formed on the first metal layer, and a second metal layer formed on the metal oxide layer.

In an exemplary method of manufacturing a TFT substrate having a scan line, a data line and a switching device that is electrically connected to the scan line and the data line, according to the present invention, a first metal layer is formed on a transparent substrate. The first metal layer is exposed to oxygen gas (O₂) to form a metal oxide layer. A second metal layer is formed on the metal oxide layer, and then the first metal layer, the metal oxide layer and the second metal layer are patterned to form the scan line.

In an exemplary display device according to the present invention, the display device includes a first substrate, a second substrate and a liquid crystal layer. The first substrate includes a scan line, a data line and a switching device electrically connected to the data line and the scan line. The second substrate faces the first substrate. The liquid crystal layer is disposed between the first and second substrates. At least one of the scan line and the data line includes at least two metal layers and a metal oxide layer disposed between the metal layers.

Therefore, the metal oxide layer prevents corrosion of metal layers, so that deterioration of metal wiring is reduced.

### BRIEF DESCRIPTION OF THE DRAWINGS

The above and other features and advantages of the present invention will become more apparent by describing in detail exemplary embodiments thereof with reference to the accompanying drawings, in which:

FIG. 1 is a layout illustrating an exemplary embodiment of a TFT substrate according to the present invention;

FIG. 2 is a cross-sectional view taken along line I-I′ in FIG. 1;

FIGS. 3A through 3E are cross-sectional views illustrating steps of manufacturing the TFT substrate in FIG. 1;

FIG. 4 is a perspective view illustrating a multi-layered structure of metal wiring of the TFT substrate in FIG. 1; and

FIG. 5 is a graph showing an amount of material between first and second metal layers.

### DETAILED DESCRIPTION OF THE INVENTION

It should be understood that the exemplary embodiments of the present invention described below may be varied and modified in many different ways without departing from the inventive principles disclosed herein, and that the scope of the present invention is therefore not limited to these particular embodiments. Rather, these embodiments are provided so that this disclosure will be thorough and complete, and will fully convey the concept of the invention to those skilled in the art by way of example and not of limitation.

Hereinafter, exemplary embodiments of the present invention will be described in detail with reference to the accompanied drawings. It is noted that various changes, substitutions and alterations can be made herein without departing from the spirit and scope of the invention as defined by embodiments that will be described below. The embodiments are only examples for showing the sprit of the present invention to a person skilled in the art. In the figures, the thickness of layers is exaggerated for clarity. The term “disposed on” means “disposed over”. In other words, something may be disposed therebetween. The term “disposed directly on” means that nothing is disposed therebetween.

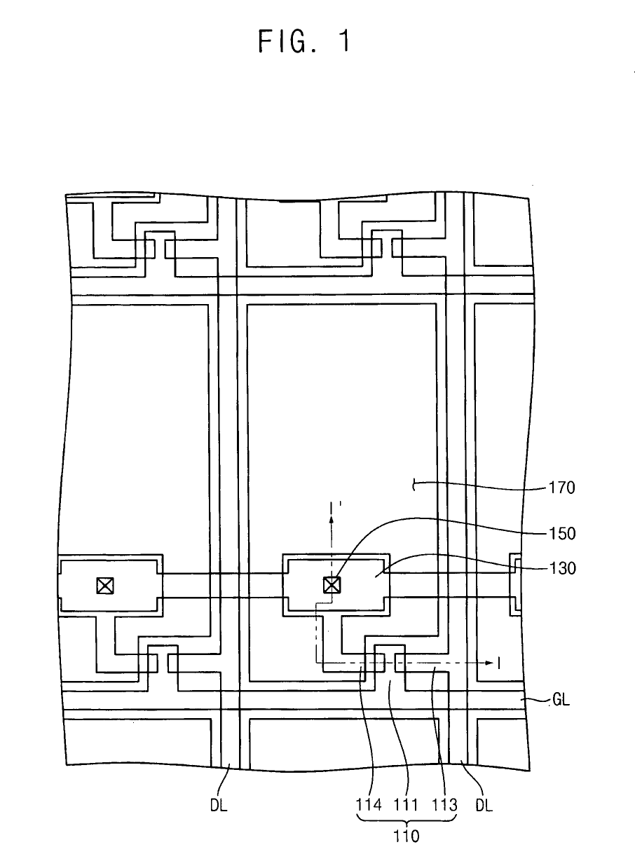

FIG. 1 is a layout illustrating an exemplary embodiment of a TFT substrate according to the present invention.

Referring to FIG. 1, a TFT substrate includes a plurality of scan lines (or gate lines) GL, a plurality of data lines (or source lines) DL, and a plurality of pixel regions. The scan lines GL extend along a first direction, and the data lines DL extend along a second direction that is substantially perpendicular to the first direction. Each of the pixel regions is defined by one of the scan lines GL and one of the data lines DL.

Each of the pixel regions includes a switching device 110, a storage capacitor 130, and a pixel electrode 170. In an exemplary embodiment, a TFT may be employed as the switching device 110. The storage capacitor 130 is electrically connected to the switching device 110. The pixel electrode 170 corresponds to one terminal of a liquid crystal capacitor (CLC).

The switching device 110 includes a gate electrode 111 that is electrically connected to one of the scan lines GL, a source electrode 113 that is electrically connected to one of the data lines DL, and a drain electrode 114 that is electrically connected to the pixel electrode 170. A semiconductor layer (not shown) is disposed between the gate electrode 111, and the source and drain electrodes 113 and 114.

The storage capacitor 130 includes a first electrode and a second electrode. The first electrode of the storage capacitor 130 and the scan lines GL may be formed from the same metal layer. The second electrode of the storage capacitor 130 and the drain electrode 114 may also be formed from the same metal layer. When the switching device 110 is turned off, the storage capacitor 130 maintains a pixel voltage applied to the liquid crystal capacitor (CLC) during one frame.

In an exemplary embodiment, the gate electrode 111 extends from the scan lines GL. The first electrode of the storage capacitor 130 may have a multi-layered structure including metal layers, and at least one metal oxide layer is disposed between the metal layers. The metal oxide layer prevents the metal layers including, but not limited to, an aluminum (Al) layer, an aluminum alloy layer, etc. from corrosion due to a developing solution of photolithography including, but not limited to, tetra methyl ammonium hydroxide (TMAH) during a photolithography process.

In an exemplary embodiment, the metal oxide layer is formed between the metal layers preventing electrons from transferring between the metal layers. Therefore, an electrochemical cell is not generated between the metal layers, so that the metal layers are not corroded.

The multi-layered metal layer includes, but is not limited to, aluminum (Al), aluminum alloy, metal of a thirteenth group of periodic table, silver (Ag), silver alloy, copper (Cu), copper alloy, molybdenum (Mo), molybdenum alloy, chromium (Cr), tantalum (Ta), titanium (Ti), etc. The multi-layered metal layer may be employed by the scan lines GL. In an alternative exemplary embodiment, the multi-layered metal layer may be employed by the data lines DL or both the scan lines GL and the data lines DL.

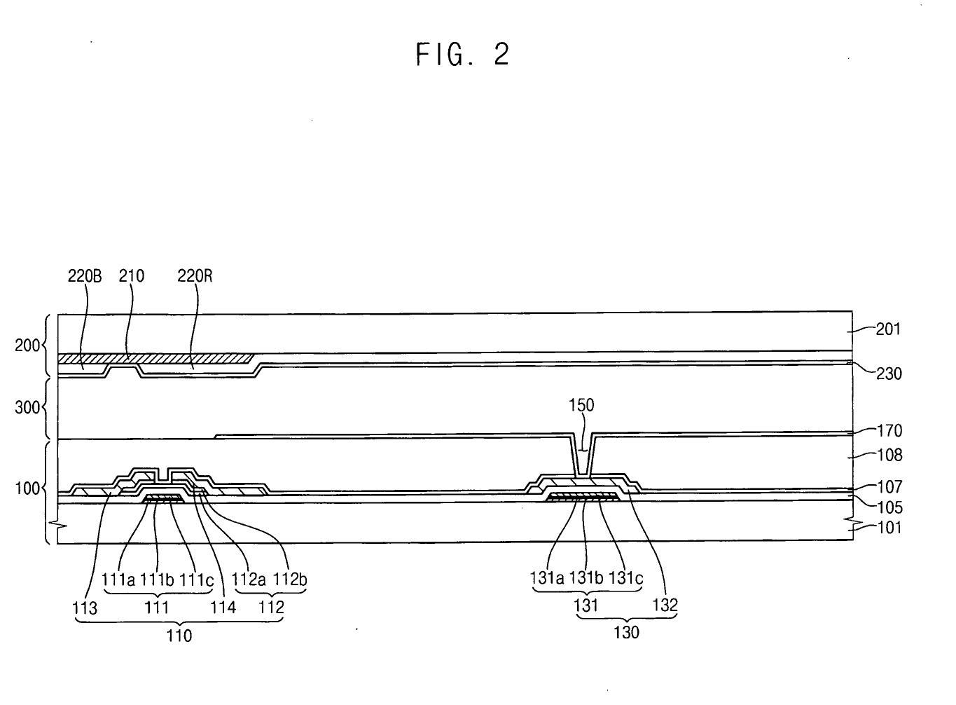

FIG. 2 is a cross-sectional view taken along line I-I′ in FIG. 1. In a particular exemplary embodiment, metal wirings such as the scan lines GL and the data lines DL include a double-layered structure.

Referring to FIG. 2, a display panel includes a TFT substrate 100, a color filter substrate 200 facing the TFT substrate 100, and a liquid crystal layer 300 disposed between the TFT substrate 100 and the color filter substrate 200.

The TFT substrate 100 includes a first transparent substrate 101. A gate electrode layer may be formed on the first transparent substrate 101, and the gate electrode layer may be patterned to form the gate electrode 111 of the switching device 110, the scan lines GL, and the first electrode of the storage capacitor 130.

The gate electrode layer includes a first metal layer 111a, a second metal layer 111c, and a metal oxide layer 111b disposed between the first and second metal layers 111a and 111c. The first metal layer 111a may be made of materials including, but not limited to, aluminum (Al), aluminum alloy, silver (Ag), silver alloy, copper (Cu), copper alloy or a mixture thereof, and the second metal layer 111c may be made of materials including, but not limited to, molybdenum (Mo), molybdenum alloy, chromium (Cr), chromium alloy, tantalum (Ta), tantalum alloy, titanium (Ti), titanium alloy and a mixture thereof.

The first metal layer 111a may be made of materials including, but not limited to, aluminum (Al) or aluminum alloy such as aluminum neodymium (Al—Nd), and the second metal layer 111c may be made of materials including, but not limited to, molybdenum (Mo). Aluminum (Al) is an amphoteric material, which means that it reacts to both acids and bases. Therefore, the first metal layer 111a is easily corroded by developing solution of photolithography.

In an exemplary embodiment, in order to prevent corrosion of the first metal layer 111a the metal oxide layer 111b is formed on the first metal layer 111a, and the second metal layer 111c is formed on the metal oxide layer 111b. The first metal layer 111a is exposed to oxygen gas of about 10 sccm for about six seconds, so that a surface of the first metal layer 111a is oxidized to form the metal oxide layer 111b.

The metal oxide layer 111b may have a thickness of less than about 100 angstroms.

The storage capacitor 130 is formed from the gate electrode layer and includes the first electrode 131 and the second electrode 132. The first electrode 131 of the storage capacitor 130 includes a first metal layer 131a, a second metal layer 131c, and a metal oxide layer 131b disposed between the first and second metal layers 131a and 131c. The scan lines GL formed from the gate electrode layer also include the first metal layer, the second layer, and the metal oxide layer.

A gate insulation layer 105 is formed on the first transparent substrate 101 having the gate electrode layer formed thereon. A semiconductor layer 112 is formed on the gate insulation layer 105 and includes an activation layer 112a and an ohmic contact layer 112b. The semiconductor layer 112 is disposed on a region of the gate insulation layer 105 corresponding to the gate electrode 111.

A source and drain metal layer is formed on the first transparent substrate 101 having the semiconductor layer 112 formed thereon. The source and drain metal layer may be patterned to form the data lines DL, the source electrode 113, the drain electrode 114, and the second electrode 132 of the storage capacitor 130.

A passivation layer 107 is formed on the first transparent substrate 101 having the data lines DL, the source electrode 113, the drain electrode 114, and the second electrode 132 formed thereon. An insulation layer 108 may optionally be formed on the passivation layer 107.

The passivation layer 107 and the insulation layer 108 may be etched to form a contact hole 150 that exposes a portion of the drain electrode 114. An optically transparent and electrically conductive layer may be formed on the insulation layer 108. The optically transparent and electrically conductive layer may be patterned to form the pixel electrode 170. The pixel electrode 170 is electrically connected to the drain electrode 114 through the contact hole 150.

The color filter substrate 200 includes a second transparent substrate 201, a light-blocking layer 210, a color filter pattern, and a common electrode 230. The light-blocking layer 210 is formed on the second transparent substrate 201. The light-blocking layer 210, disposed over the pixel electrode, includes a plurality of openings arranged in a matrix shape. The color filter pattern is formed on the second transparent substrate 201 exposed through the openings of the light-blocking layer 210. The color filter pattern includes a red color filter 220R, a green color filter (not shown), and a blue color filter 220B. When white light passes through the red, green, and blue color filters red, green, and blue colored lights exit the red, green, and blue color filters, respectively.

The common electrode 230 is formed on the second transparent substrate 201 having the color filter pattern formed thereon. The common electrode 230 faces the pixel electrode 170 of the TFT substrate 100. A reference voltage may be applied to the common electrode 230. The liquid crystal capacitor CLC is defined by the common electrode 230, the pixel electrode 170, and the liquid crystal layer 300 disposed between the common electrode 230 and the pixel electrode 170. The color filter substrate 200 may optionally include a leveling layer (not shown) disposed between the color filter pattern and the common electrode 230. The leveling layer may protect the color filter pattern level the surface of the color filter layer.

When a voltage is applied to the pixel electrode 170, an electric field is generated between the pixel electrode 170 and the common electrode 230. The electric field alters the arrangement of the liquid crystal molecules of the liquid crystal layer 300 changing the optical transmissivity of the liquid crystal layer to display an image.

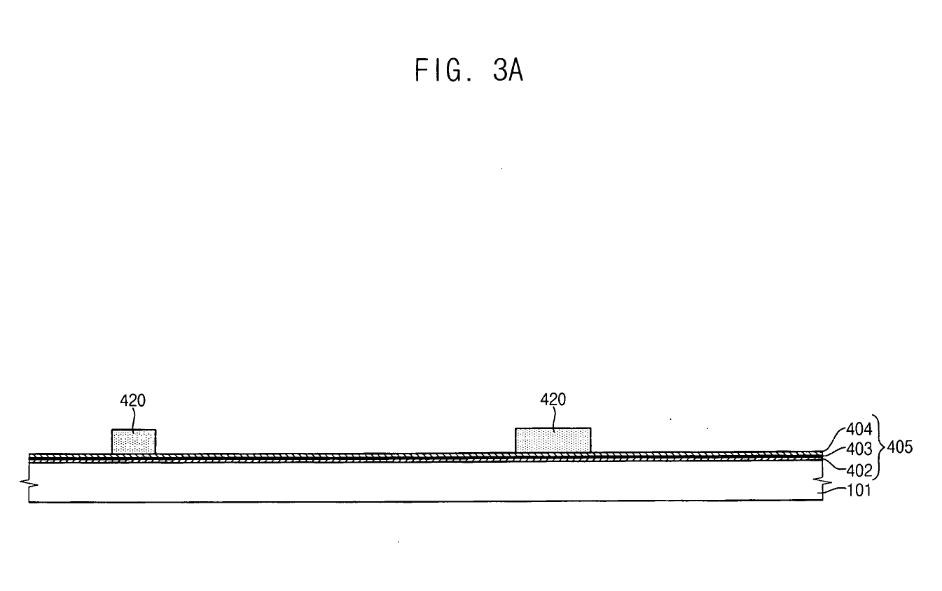

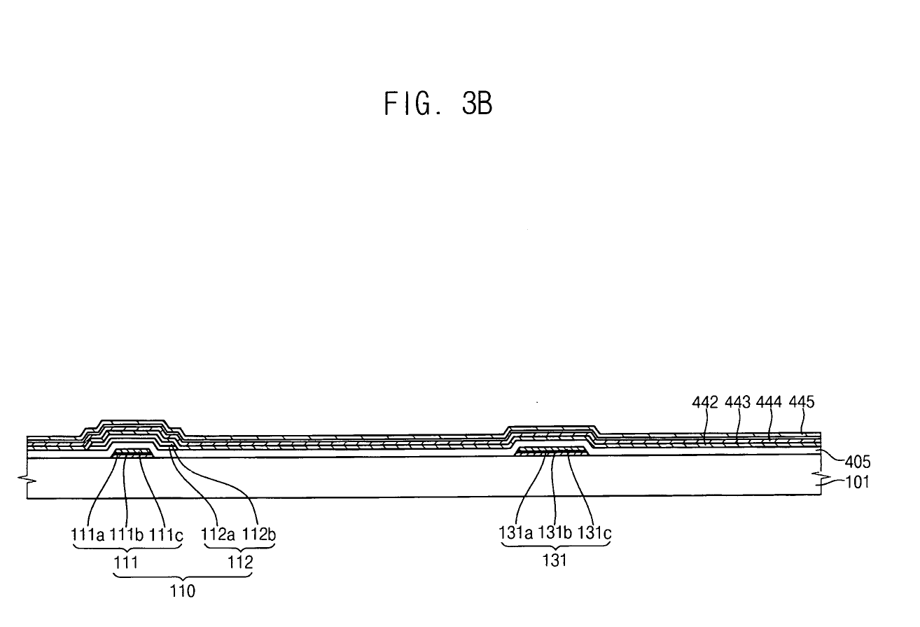

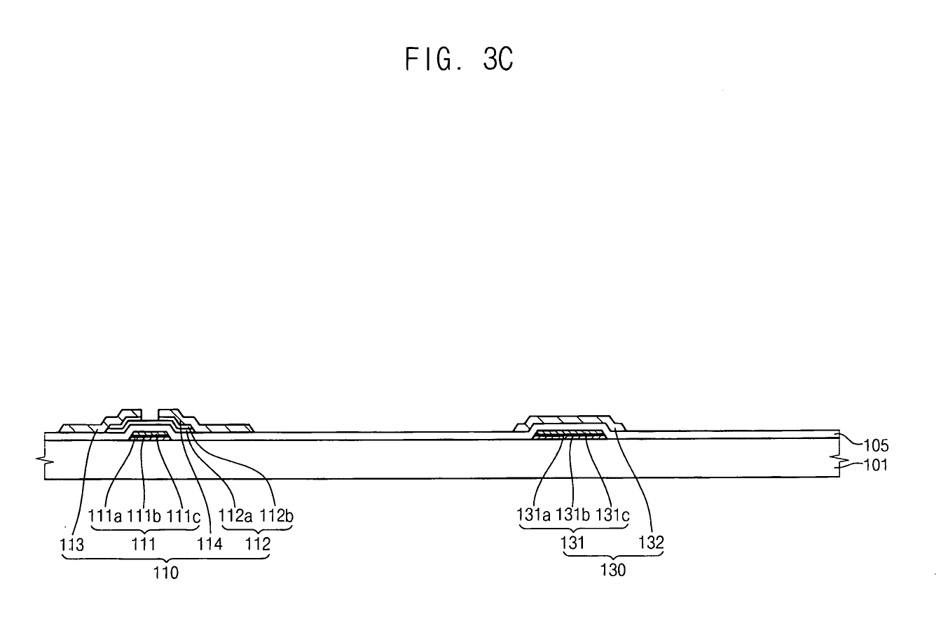

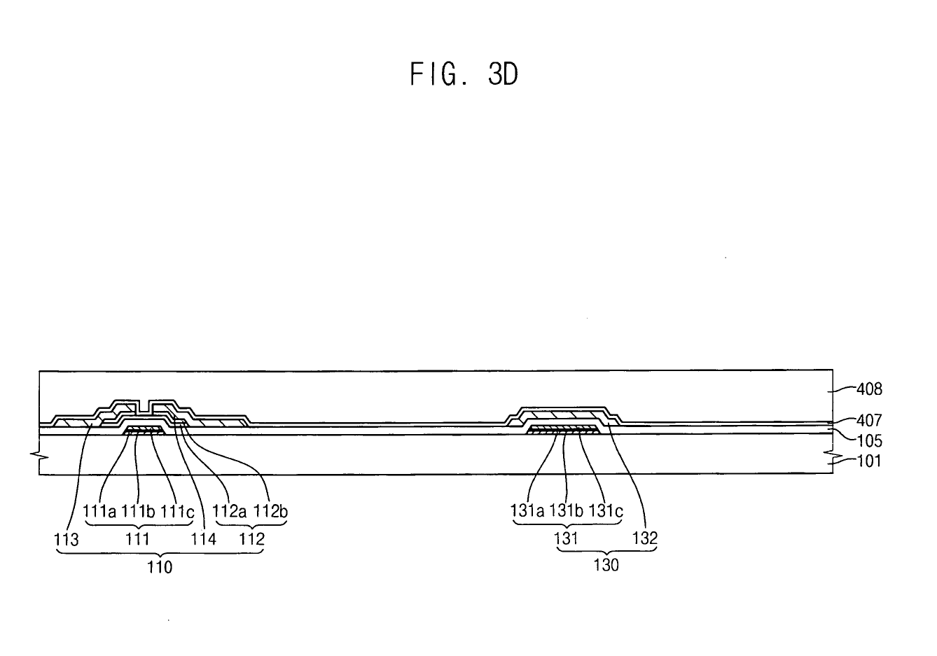

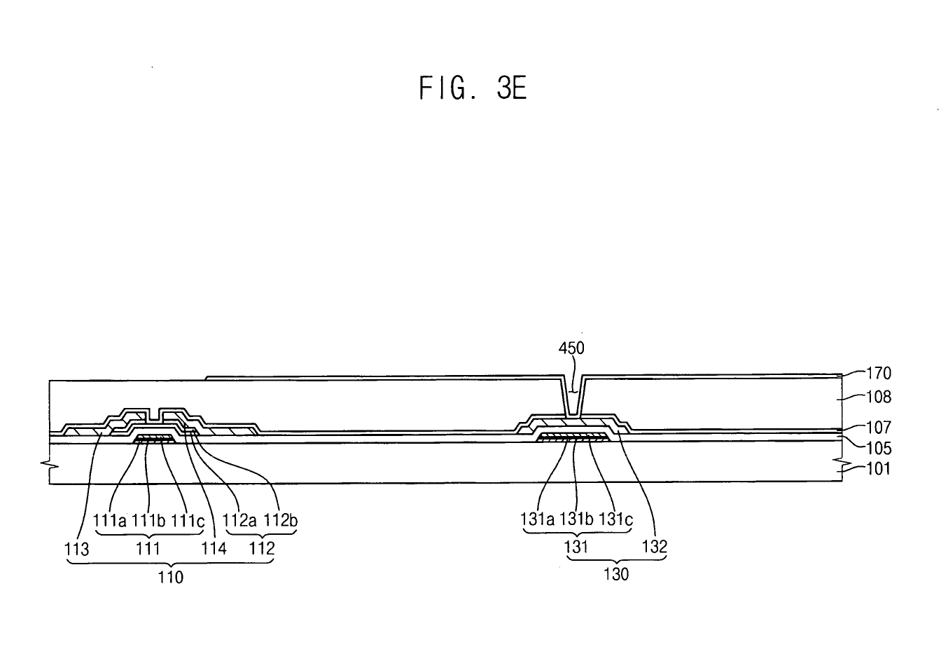

FIGS. 3A through 3E are cross-sectional views illustrating steps of manufacturing the TFT substrate in FIG. 1. Referring to FIG. 3A, the gate electrode layer 405 including the first metal layer 402, the metal oxide layer 403 and the second metal layer 404 is formed on the first transparent substrate 101. In an exemplary embodiment, the first metal layer 402 may be made of materials including, but not limited to, aluminum (Al) or aluminum alloy. The first metal layer 402 may be formed on the first transparent substrate 101 by methods including, but not limited to, a sputtering method in a first chamber, and then oxygen (O₂) gas of about 10 sccm is injected into the first chamber for about six seconds to form the metal oxide layer 403 having a thickness of less than about 100 angstroms. However, it is also contemplated that the first metal layer 402 may be formed by various other methods.

The first transparent substrate 101 having the first metal layer 402 and the metal oxide layer 403 formed thereon is transferred to a second chamber. In the second chamber, the second metal layer 404 including, but not limited to, molybdenum (Mo) is formed on the metal oxide layer 403.

In an alternative exemplary embodiment, when the first metal layer 402 is formed on the first transparent substrate 101 in the first chamber, the first transparent substrate 101 having the first metal layer 402 is transferred to the second chamber, and then oxygen (O₂) gas of about 10 sccm is injected into the second chamber for about six seconds to form the metal oxide layer 403 having a thickness of less than about 100 angstroms. The second metal layer 404 including, but not limited to, molybdenum (Mo) is formed on the metal oxide layer 403 in the second chamber.

The gate electrode layer 405 may be patterned through a photolithography process. In an exemplary embodiment, a photoresist layer is formed on the gate electrode layer 405 and patterned, so that the photoresist layer is present only in regions corresponding to the gate electrode and the first electrode of the storage capacitor. The first transparent substrate 101 having the gate electrode layer 405 may be patterned to form the scan lines GL, the gate electrodes, and the first electrode of the storage capacitor through the photoresist layer.

Referring to FIG. 3B, the scan lines (not shown), the gate electrode 111 and the first electrode 131 of the storage capacitor are formed on the first transparent substrate 101. The gate electrode 111 includes the first metal layer 111a, the metal oxide layer 111b and the second metal layer 111c. The first electrode 131 includes the first metal layer 131a, the metal oxide layer 131b and the second metal layer 131c. The scan lines (not shown) include the first metal layer, the metal oxide layer and the second metal layer.

The gate insulation layer (not shown) is formed on the first transparent substrate 101 having the gate electrode 111, the first electrode 131 of the storage capacitor and the scan lines (not shown) formed thereon. A primitive activation layer is formed on the gate insulation layer, and a primitive ohmic contact layer is formed on the primitive activation layer. The primitive activation layer may be made of amorphous silicon (a-Si), and the primitive ohmic contact layer may be made of amorphous silicon having dopant (n⁺ a-Si).

The primitive activation layer and the primitive ohmic contact layer are patterned in photolithography process to form the activation layer 112a and the ohmic contact layer 112b disposed over the gate electrode 111, respectively. The photolithography process includes forming a photoresist layer, patterning the photoresist layer, exposing, developing and etching processes.

A third metal layer 442, a fourth metal layer 443, a metal oxide layer 444 and a fifth metal layer 445 are formed in sequence on the first transparent substrate 101 having the activation layer 112a and the ohmic contact layer 112b formed thereon to form a source and drain metal layer. In an exemplary embodiment, the third and fifth metal layers 442 and 445 are made of the same material. The third and fifth metal layers 442 and 445 may be made of materials including, but not limited to, molybdenum (Mo) or molybdenum alloy. The fourth metal layer 443 may be made of materials including, but not limited to, aluminum (Al) or aluminum alloy. The metal oxide layer 444 may be disposed between the fourth and fifth metal layers 443 and 445 to prevent corrosion of the fourth metal layer 443.

Referring to FIG. 3C, the source and drain metal layer is patterned to form the source electrode 113, the drain electrode 114, and data lines DL. In an exemplary embodiment, the source electrode 113, the drain electrode 114, and data lines DL have a multi-layered structure as shown in FIG. 3B. In an alternative exemplary embodiment, the source electrode 113, the drain electrode 114 and data lines DL may have a single-layered structure as shown in FIG. 3C.

Referring to FIG. 3D, the ohmic contact layer 112b disposed between the source and drain electrodes 113 and 114 is etched to form a channel layer of the switching device 110. A passivation layer 407 is formed on the first transparent substrate 101 having the source and drain electrodes 113 and 114. An insulation layer 408 may optionally be formed on the passivation layer 407.

The insulation layer 408 may be made of an inorganic material including, but not limited to, silicon nitride, silicon oxide, etc. or an organic material having a relatively low dielectric constant including, but not limited to, acryl resin, Teflon, benzocyclobutene (BCB)-based polymers, Cytop, perfluorocyclobutane (PFCB) polymers, etc.

Referring to FIG. 3E, the passivation layer 107 and the insulation layer 108 in FIG. 3D are patterned to form the contact hole 450 through a photolithography process, exposing a portion of the drain electrode are completed.

An optically transparent and electrically conductive layer is formed on the insulation layer 108. The optically transparent and electrically conductive layer may be made of materials including, but not limited to, indium tin oxide (ITO), indium zinc oxide (IZO), etc. The optically transparent and electrically conductive layer may be patterned to form the pixel electrode 170. In an exemplary embodiment, the pixel electrode 170 is electrically connected to TFT 110.

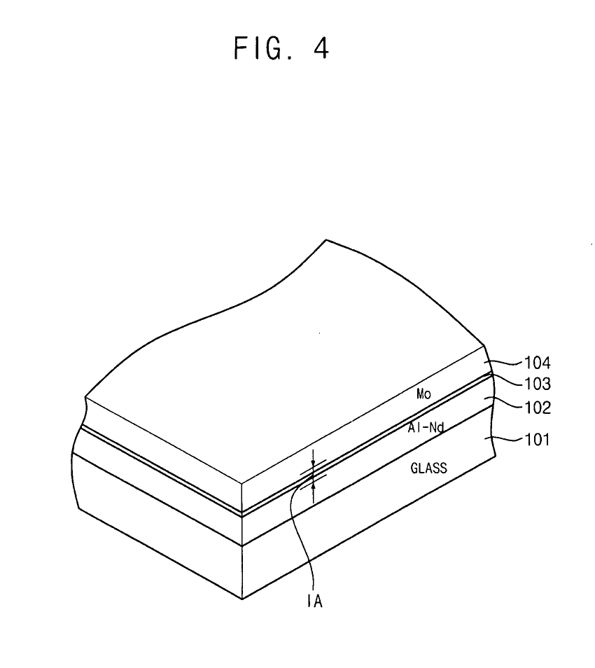

FIG. 4 is a perspective view illustrating a multi-layered structure of metal wiring of the TFT substrate in FIG. 1.

Referring to FIG. 4, the first metal layer 102 is formed on the first transparent substrate 101, the metal oxide layer 103 is formed on the first metal layer 102 and the second metal layer 104 is formed on the metal oxide layer 103.

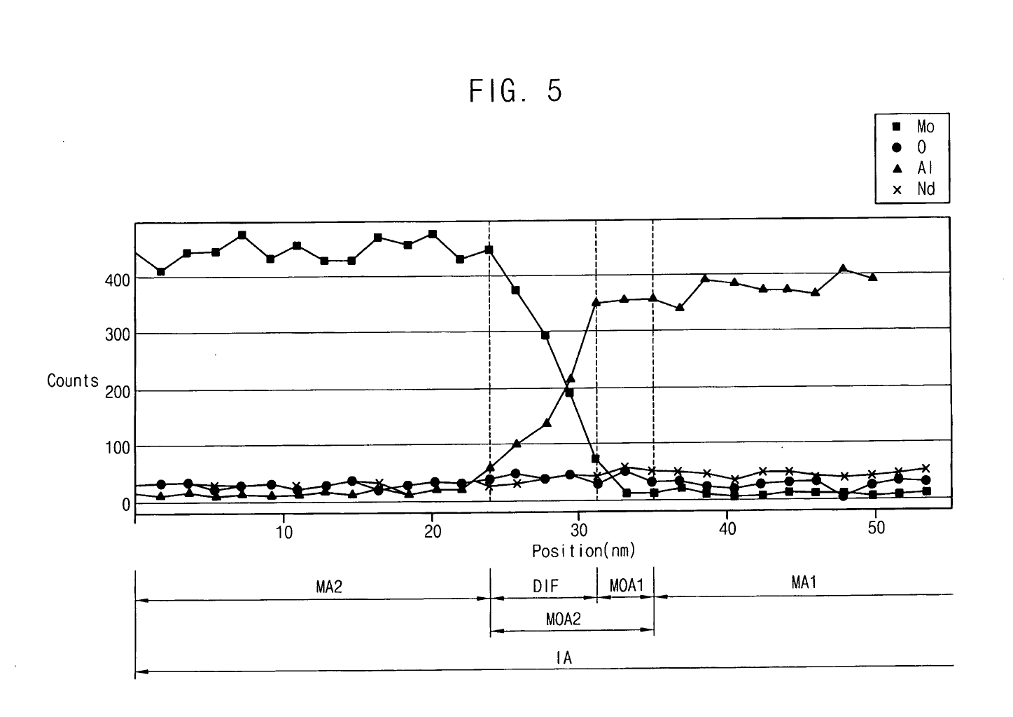

FIG. 5 is a graph showing an amount of material between first and second metal layers 102 and 104 as shown in FIG. 4.

Referring to FIG. 5, a thickness of interface region IA between the first and second metal layers is about 50 nm. The interface region IA includes a first metal region MA1 including aluminum (Al), a second metal region MA2 including molybdenum (Mo), and a diffusion region DIF.

In an exemplary embodiment, the first metal layer including aluminum neodymium (Al—Nd) is formed on the transparent substrate and the first metal layer is exposed to oxygen (O₂) for about six seconds to form a first metal oxide layer MOAL having a thickness of about 40 angstroms.

Then, the second metal layer including molybdenum (Mo) is formed on the first metal oxide layer MOAL. During forming the second metal layer, a portion of oxygen (O₂) is diffused into the second metal layer to form the diffusion region DIF. A second metal oxide layer MOA2 including oxygen (O₂) between the first and second metal regions MA1 and MA2 is formed. The thickness of the second metal oxide layer MOA2 is about less than about 100 angstroms. The second metal oxide layer MOA2 corresponds to the metal oxide layer described above.

The metal oxide layer prevents electrons from transferring between the metals to prevent corrosion of the first metal layer.

The results of several experiments will be now be explained. In the experiments a first metal layer was formed on a first transparent substrate and the first metal layer was exposed to oxygen for a varying duration. The second metal layer was then formed on the first metal layer. Finally, the resistance of the first metal layer was measured to determine the extent of corrosion present in the first metal layer.

TABLE 1

| | | | Resistance measured |
|---|---|---|---|
| | O₂ | | after dipping into |
| | exposure | Initial resistance | developing solution |
| | time | after exposure | for 60 seconds |
| Experimental | 0 sec. | 0.498Ω | 3.195Ω |
| example 1 | | | |
| Experiment | 6 sec. | 0.497Ω | 0.781Ω |
| example 2 | | | |
| Experiment | 12 sec. | 0.488Ω | 0.836Ω |
| example 3 | | | |
| Experiment | 18 sec. | 0.499Ω | 0.864Ω |
| example 4 | | | |
| Experiment | 24 sec. | 0.489Ω | 0.843Ω |
| example 5 | | | |

Table 1 is a result of the experiment for testing an amount of corrosion of the first metal layer changing a time for exposing the first metal layer to oxygen (O₂).

### EXPERIMENTAL EXAMPLE 1

Referring to FIG. 4, the first metal layer 102 including aluminum neodymium (Al—Nd) was formed on the first transparent substrate 101. The first metal layer 102 was not exposed to oxygen (O₂), and the second metal layer 104 including molybdenum (Mo) was formed on the first metal layer 102, so that no metal oxide layer 102 was disposed between the first and second metal layers 102 and 104.

Referring to Table 1, a resistance measured from the first metal layer 102 was about 0.498Ω, and a resistance measured from the first metal layer 102 that was dipped into a developing solution for about 60 seconds was about 3.195Ω. This result shows that the first metal layer was severely corroded.

### EXPERIMENTAL EXAMPLE 2

Referring to FIG. 4, the first metal layer 102 including aluminum neodymium (Al—Nd) was formed on the first transparent substrate 101. The first metal layer 102 was exposed to oxygen (O₂) for about 6 seconds, and the second metal layer 104 including molybdenum (Mo) was formed on the first metal layer 102.

Referring to table 1, a resistance measured from the first metal layer 102 was about 0.497Ω, and a resistance measured from the first metal layer 102 that was dipped into a developing solution for about 60 seconds was about 0.781Ω. This result shows a relatively small amount of the first metal layer was corroded.

### EXPERIMENTAL EXAMPLE 3

Referring to FIG. 4, the first metal layer 102 including aluminum neodymium (Al—Nd) was formed on the first transparent substrate 101. The first metal layer 102 was exposed to oxygen (O₂) for about 12 seconds, and the second metal layer 104 including molybdenum (Mo) is formed on the first metal layer 102.

Referring to Table 1, a resistance measured from the first metal layer 102 was about 0.488Ω, and a resistance measured from the first metal layer 102 that was dipped into a developing solution for a bout 60 seconds was about 0.836Ω. This result shows a relatively small amount of the first metal layer was corroded.

### EXPERIMENTAL EXAMPLE 4

Referring to FIG. 4, the first metal layer 102 including aluminum neodymium (Al—Nd) was formed on the first transparent substrate 101. The first metal layer 102 was exposed to oxygen (O₂) for about 18 seconds, and the second metal layer 104 including molybdenum (Mo) was formed on the first metal layer 102.

Referring to table 1, a resistance measured from the first metal layer 102 was about 0.499Ω, and a resistance measured from the first metal layer 102 that was dipped into a developing solution for a bout 60 seconds was about 0.864Ω. This result shows a relatively small amount of the first metal layer was corroded.

### EXPERIMENTAL EXAMPLE 5

Referring to FIG. 4, the first metal layer 102 including aluminum neodymium (Al—Nd) was formed on the first transparent substrate 101. The first metal layer 102 was exposed to oxygen (O₂) for about 24 seconds, and the second metal layer 104 including molybdenum (Mo) was formed on the first metal layer 102.

Referring to Table 1, a resistance measured from the first metal layer 102 was about 0.489Ω, and a resistance measured from the first metal layer 102 that was dipped into a developing solution for about 60 seconds is about 0.843Ω. This result shows a relatively small amount of the first metal layer was corroded.

According to the present invention, a metal wiring having a multi-layered structure includes metal oxide layer formed at interface between metal layers. The metal oxide layer prevents corrosion of the metal layers, so that deterioration of the metal wiring is reduced.

Having described the exemplary embodiments of the present invention and its advantages, it is noted that various changes, substitutions and alterations can be made herein without departing from the spirit and scope of the invention as defined by appended claims.

What is claimed is:

1. A metal wiring comprising:
a first metal layer formed on a substrate;
a metal oxide layer formed on the first metal layer to prevent corrosion of the first metal layer; and
a second metal layer formed on the metal oxide layer.

2. The metal wiring of claim 1, further comprising a third metal layer formed on the second metal layer, wherein the second and third metal layers include substantially same metal.

3. The metal wiring of claim 1, wherein a thickness of the metal oxide layer is less than about 100 angstroms.

4. A method of forming a metal wiring, comprising:
forming a first metal layer on a substrate;
exposing the first metal layer to oxygen gas (O₂) to form a metal oxide layer on the first metal layer;
forming a second metal layer on the metal oxide layer; and
patterning the first metal layer, the metal oxide layer and the second metal layer to form the metal wiring.

5. The method of claim 4, wherein the metal oxide layer is configured to prevent a corrosion of the first metal layer during patterning the first metal layer, the metal oxide layer and the second metal layer.

6. The method of claim 4, wherein the metal oxide layer is configured to prevent electrons from transferring between the first and second metal layers.

7. A thin film transistor (TFT) substrate comprising:
a transparent substrate;
a scan line formed on the transparent substrate;
a data line formed on the transparent substrate, the data line being electrically insulated from the scan line;
a switching device including a gate electrode that is electrically connected to the scan line, a source electrode that is electrically connected to the data line, and a drain electrode; and
a pixel electrode that is electrically connected to the drain electrode, wherein at least one of the scan line and the data line includes a first metal layer, a metal oxide layer formed on the first metal layer, and a second metal layer formed on the metal oxide layer.

8. The TFT substrate of claim 7, further comprising a third metal layer disposed between the transparent substrate and the first metal layer.

9. The TFT substrate of claim 8, wherein the second and third metal layers comprise a substantially same metal.

10. The TFT substrate of claim 7, further comprising a storage capacitor including a first electrode comprising the first metal layer, the metal oxide layer and the second metal layer, and a second electrode that is electrically connected to the drain electrode of the switching device.

11. The TFT substrate of claim 7, wherein the first metal layer includes any one of aluminum (Al), aluminum alloy, silver (Ag), silver alloy, copper (Cu), copper alloy and a mixture thereof.

12. The TFT substrate of claim 7, wherein the second metal layer includes any one of molybdenum (Mo), molybdenum alloy, chromium (Cr), chromium alloy, tantalum (Ta), tantalum alloy, titanium (Ti), titanium alloy and a mixture thereof.

13. The TFT substrate of claim 7, wherein the metal oxide layer has a thickness less than about 100 angstroms.

14. A method of manufacturing a thin film transistor (TFT) substrate having a scan line, a data line and a switching device that is electrically connected to the scan line and the data line, comprising:
forming a first metal layer on a transparent substrate;
exposing the first metal layer to oxygen gas (O₂) to form a metal oxide layer;
forming a second metal layer on the metal oxide layer; and
patterning the first metal layer, the metal oxide layer and the second metal layer to form the scan line.

15. The method of claim 14, wherein the data line is formed by:
forming a third metal layer on a transparent substrate;
forming a fourth metal layer on the third metal layer;
exposing the fourth metal layer to oxygen gas (O₂) to form a metal oxide layer;
forming a fifth metal layer having substantially same metal as that of the third metal layer on the metal oxide layer; and
patterning the third and fourth metal layers, the metal oxide layer and the fifth metal layer to form the data line.

16. The method of claim 14, wherein the first metal layer is exposed to the oxygen gas (O₂) with a concentration of about 10 sccm for about 6 seconds.

17. The method of claim 14, wherein the metal oxide layer has a thickness less than about 100 angstroms.

18. The method of claim 15, wherein the first metal layer includes any one of aluminum (Al), aluminum alloy, silver (Ag), silver alloy, copper (Cu), copper alloy and a mixture thereof.

19. The method of claim 15, wherein the second metal layer includes any one of molybdenum (Mo), molybdenum alloy, chromium (Cr), chromium alloy, tantalum (Ta), tantalum alloy, titanium (Ti), titanium alloy and a mixture thereof.

20. A display device comprising:
a first substrate including a scan line, a data line and a switching device electrically connected to the data line and the scan line;
a second substrate facing the first substrate; and
a liquid crystal layer disposed between the first and second substrate, wherein at least one of the scan line and the data line includes at least two metal layers and a metal oxide layer disposed between the metal layers.

21. The display device of claim 20, wherein the scan line includes a first metal layer, the metal oxide layer formed on the first metal layer and a second metal layer formed on the metal oxide layer.

22. The display device of claim 21, wherein the first metal layer comprises aluminum (Al), and the second metal layer comprises molybdenum (Mo).

23. The display device of claim 20, wherein the data line includes a first metal layer, the metal oxide layer formed on the first metal layer and a second metal layer formed on the metal oxide layer.

24. The display device of claim 23, wherein the first metal layer comprises aluminum (Al), and the second metal layer comprises molybdenum (Mo).

25. The display device of claim 20, wherein the data line includes a first metal layer, a second metal layer formed on the first metal layer, the metal oxide layer formed on the second metal layer and a third metal layer formed on the metal oxide layer.

26. The display device of claim 25, wherein the first and third metal layers comprise molybdenum (Mo), and the second metal layer comprises aluminum.

27. The display device of claim 20, wherein the metal oxide layer has a thickness less than about 100 angstrom.
